(19) United States
(12) Patent Application Publication
(10) Pub. No.: US 2016/0225694 A1
(43) Pub. Date: Aug. 4, 2016

(54) HIGH CONDUCTIVITY HIGH FREQUENCY VIA FOR ELECTRONIC SYSTEMS

(71) Applicants: Hans-Joachim BARTH, Munich (DE); Reinhard MAHNKOPF, Oberhaching (DE); Wolfgang MOLZER, Ottobrunn (DE); Harald GOSSNER, Riemerling (DE); Christian MUELLER, Bottrop (DE)

(72) Inventors: Hans-Joachim BARTH, Munich (DE); Reinhard MAHNKOPF, Oberhaching (DE); Wolfgang MOLZER, Ottobrunn (DE); Harald GOSSNER, Riemerling (DE); Christian MUELLER, Bottrop (DE)

(21) Appl. No.: 14/411,382

(22) PCT Filed: Jun. 27, 2013
(86) PCT No.: PCT/US2013/048323

§ 371 Date: Dec. 24, 2014

(51) Int. Cl. H01L 23/48; H01L 23/532; H01L 21/768; H01L 23/66

(52) U.S. Cl. CPC H01L 23/481; H01L 23/66; H01L 23/53276; H01L 23/53228; H01L 23/53242; H01L 21/76898; H01L 21/76831; H01L 21/76877; H01L 2223/6622; H01L 2221/1094

(57) ABSTRACT

A through silicon via is described that has conductivity at high frequencies. In one example, the via includes a channel through at least a portion of a silicon die. A first conductive layer has a first electrical conductivity. A second conductive layer covers the outer surface of the first conductive layer and has a second electrical conductivity higher than the first electrical conductivity.

### FIELD

The present description relates to the field of conductive vias used in semiconductor dies and packages and, in particular, to vias with enhanced conductivity at high frequencies.

### BACKGROUND

Semiconductor dies are typically formed using a silicon substrate. The substrate may form a carrier or the surface upon which the circuitry is built. Channels are drilled, bored, or etched through the silicon to allow metal contacts at one level in the silicon to be connected to another level in the silicon. The channels are referred to as through silicon vias. In order to make an electrical connection, the vias are lined or filled with a conductive material such as copper or aluminum. The vias are used in a variety of different ways. One way is to connect the circuitry formed on one side of the substrate to external connections on the other side of the substrate. These connection may be for power or for data. In some cases, the circuitry is formed in multiple layers on top of one another and vias are used to connect circuits on different layers.

In some dies the circuits are ultimately connected to a layer of metal paths on the top of the die called the front side metallization layer. The die also has a layer of metal paths on the bottom of the die to connect to a socket, a package substrate, or some other structure. The bottom layer of metal paths is called the back side metallization layer. The front and back side layers are connected together using through silicon vias that extend between the front side and the back side.

Vias are also used in electronic and micromechanical packaging. Many types of packages have a substrate to which one or more dies are attached. The package substrate has an array of electrical connections to the die on one side. The electrical connections are usually using solder balls or wiring pads. The package substrate also has electrical connections on the other side to make an external contact to a socket, a circuit board, or some other surface. In between the connection arrays, there are one or more routing layers to allow points on the die to connect to the external points. Through silicon vias are also used to connect the different routing layers to each other.

Through silicon vias (TSVs) are normally filled with a simple metal (e.g. copper (Cu), tungsten (W), aluminum (Al) etc.). The layer stack within the opening of as typical TSV is first a dielectric, such as silicon oxide (SiO₂), to electrically isolate the Si sidewall from the metal fill. A metal diffusion barrier and adhesion layer (e.g. Ti, TiN, Ta, TaN, Ru, WN, etc,) is then used over the dielectric to prevent diffusion of metal ions from the metal fill into the Si substrate and to improve the adhesion of the metal fill in the TSV. Finally, a pure metal fill is deposited by appropriate deposition processes (e.g. electroplating, e-less plating, CVD, sputtering, PVD, etc. or a combination of these techniques).

### BRIEF DESCRIPTION OF THE DRAWING FIGURES

Embodiments of the invention are illustrated by way of example, and not by way of limitation, in the figures of the accompanying drawings in which like reference numerals refer to similar elements.

FIG. 1 is a cross-sectional side view diagram of a TSV in a silicon substrate with enhanced conductivity at high frequencies according to an embodiment of the invention.

FIG. 2A is a cross-sectional side view diagram of a TSV in a silicon substrate enhanced conductivity at high frequencies according to an embodiment of the invention.

FIG. 2B is cross-sectional top view diagram of the TSV of FIG. 2A.

FIG. 3 is a cross-sectional top view diagram of an alternative TSV with enhanced conductivity at high frequencies according to an embodiment of the invention.

FIG. 4 is a cross-sectional top view diagram of an alternative TSV with enhanced conductivity at high frequencies according to an embodiment of the invention.

FIG. 5 is a cross-sectional top view diagram of a further alternative TSV with enhanced conductivity at high frequencies according to an embodiment of the invention.

FIG. 6 is a cross-sectional top view diagram of a further alternative TSV with enhanced conductivity at high frequencies according to an embodiment of the invention.

FIG. 7A is a cross-sectional side view diagram of a portion of a TSV in a silicon substrate with enhanced conductivity at high frequencies according to an embodiment of the invention.

FIG. 7B is a process flow diagram of forming a packaged silicon die having a TSV with enhanced conductivity at high frequencies.

FIG. 8 is a cross-sectional side view diagram of a portion of a TSV in a silicon substrate enhanced conductivity at high frequencies using graphene according to an embodiment of the invention.

FIG. 9 is a block diagram of a computer system having one or more TSVs according to an embodiment of the present invention.

### DETAILED DESCRIPTION

Through silicon vias are used for both radio frequency (RF) dies, such as power amplifiers, RF front end dies, and RF transceivers, and for digital circuitry, such as central processors, baseband signal processors, graphics processor, and memory. With high frequency RF transmission circuits and with, high bit rate and high clock rate digital circuits, the TSV's of the system are called upon to transmit current or voltage at high frequencies. Even for power supply connections, the high frequency switching or mixing of digital or RF circuits cause similarly high frequency transients in the power supply signals.

For RF applications electrical conductors experience a skin effect. With increasingly higher RF frequencies, the electrical current is transported primarily in the outer surface region, or skin of the conductor. As a result, the effective or usable cross section of the conductor is reduced and the conductivity of the conductor is reduced. The higher resistance reduces current flow, and creates an impedance that reduces the responsiveness of the current to changes in load and voltage. This has a detrimental effect on the performance of the conductors and also on the performance of any connected circuits.

The performance of TSV's can be improved for higher transfer rates up to and exceeding 50 Gbit/s. At high frequencies, such as those above 500 MHz, the resistance of a conductor increases due to skin effect because current is transported only within the periphery or skin of the conductor. A new TSV filling reduces the skin effect. In embodiments, the inner part or core of the TSV is filled with an ordinary metal, such as Cu, W, Al, etc., while the outer part, next to the dielectric, is covered by a layer of lower resistance or higher conductivity material, such as silver (Ag), graphene, etc. At lower RF frequencies, the current will fill the ordinary metal of the via. At higher RF frequencies, the current will be conducted in the lower resistive skin of Ag or graphene and no longer in the Cu or W core. This leads to better RF performance and reduced power consumption.

A lower resistance, or higher conductance skin layer around the core metal fill improves performance at higher frequencies. Compared to completely filling the via with the lower resistance material would also be possible, the skin layer is less expensive. For more complex materials, such as graphene, it is much easier to form a skin, than to fill the via. For a via or more than about 1 μm in diameter size, current graphene deposition techniques such as CVD (Chemical Vapor Deposition) do not allow such a large area to be filled.

While the examples herein are presented in the context of through silicon vias in semiconductor dies and package substrates, the invention is not so limited. The structures and techniques described herein may be applied to package substrates, printed circuit boards and other types of vias in other materials. In addition, they may be applied to vias that extend through packaging materials such as inter layer dielectrics, top layer dielectrics and molding compounds such as through mold vias (TMV) of a WLB (Wafer Level Ball Grid Array Package.)

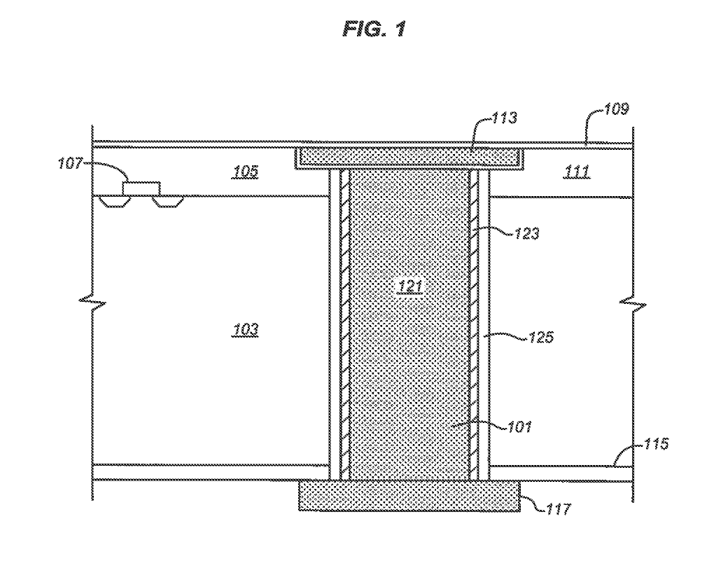

FIG. 1 is a cross-sectional side view diagram of a TSV 101 in a silicon substrate 103. The silicon substrate in this example has a transistor layer 105 formed over the substrate with circuitry formed of transistors 107 and other active and passive devices. This layer is sometimes referred to as the FEOL (Front End of the Line). The substrate has a dielectric cap layer 109 over the transistors and other devices. A front side dielectric 111 is formed over the transistors and a front side metallization 113 is formed to connect with specific contact areas provided for in the transistor layer 105. The metallization typically forms one or more different routing layers over the top of the transistors which are insulated from the transistors by the front side dielectric 111.

The entire structure is covered by a dielectric cap layer 109 and other layers may also be used depending on the particular implementation. On the opposite side of the silicon substrate 103, a dielectric back side isolation layer 115 is formed over the back side of the substrate 103. Backside metallization layers 117 are formed over the dielectric layer. The front side metallization layers and the backside metallization layers are coupled together using vias 101 as shown. While a silicon substrate is shown, the substrate may be made of a variety of other dielectric or metal materials. As an alternative to a die substrate as shown, the substrate may be part of a package, a circuit board, or some other structure. Alternatively, the via may be through only the dielectric cap, whether made of deposited layers or material or a molding compound.

In the diagram of FIG. 1 a single via 101 is shown so as not to obscure the invention. However, a semi conductor circuit die may have hundreds or thousands of vias depending on the particular implementation. The TSV 101 has a central copper filing 121. The inner copper filing has an outer surface which is surrounded by an outer layer 123 formed from a higher conductive material. This may also be thought of as a skin layer 123 because it forms a conductive skin around the inner layer. The skin layer also supports conductance through the skin effect. The outside of the skin layer 123 is surrounded by a dielectric isolation layer 125 to isolate the electrically conductive layers 121, 123 from the silicon substrate 103.

As shown, the inner past or core of the TSV is filled with an ordinary metal such as copper or tungsten while the outer part is covered by a layer of lower resistance. While silver and graphene are suggested as possible materials for the outer layer, any of a variety of other lower resistance materials may be used depending on the particular implementation. In addition, other conductive materials may be used for the inner fill layer instead of copper. Because the inner layer has a higher resistance than the outer layer the loss of conductivity with higher frequency created by the skin effect is overcome by the higher conductivity of the outer layer.

A TSV, such as that shown of FIG. 1, may be formed in any of a variety of different ways. In one example, a TSV is first etched, bored or drilled through the silicon. Typically a TSV will have a diameter of from 1 to 50 micrometers, but may be smaller or larger. This is then filled with a dielectric such as SiO₂, Si₃N₄, SiC or SiCN, or any other suitable dielectric to isolate the silicon substrate from the TSV metal. Next, a lower resistive skin layer, in this example silver or grapheme, is applied over the dielectric. As mentioned above, this skin layer transports the electrical current or signals at higher frequencies. Finally, a core conductor or metal fill is deposited into the core of the TSV. The conductor may be a metal such as copper or tungsten or aluminum or some other conductive fill such as a doped polysilicon or another other material.

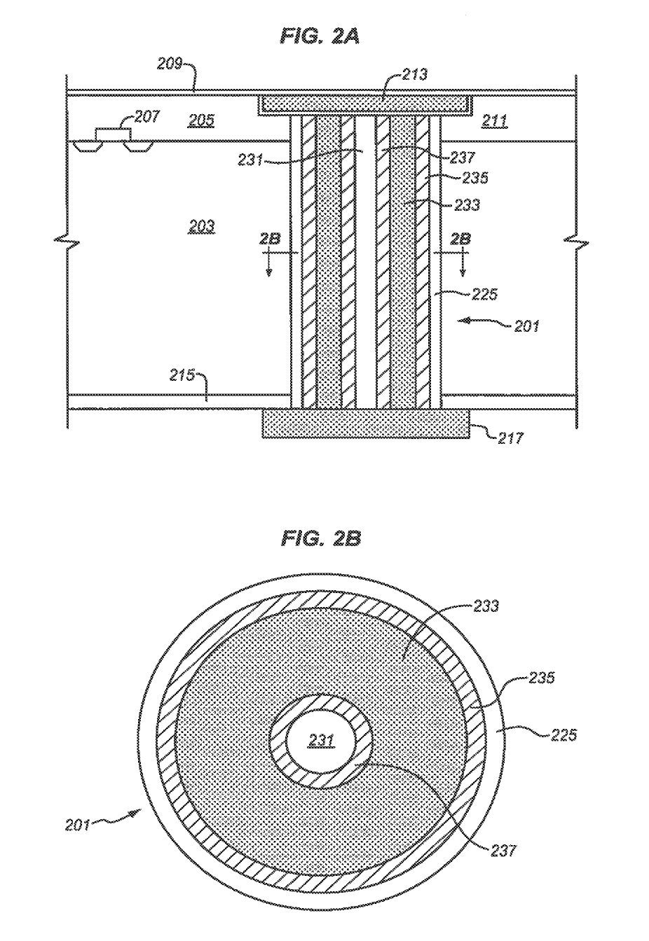

FIG. 2A shows an alternative embodiment in which multiple cylindrical or tube type metal fill layers 233 are formed in the area of the single via 201. Both sides of the metal filled tubes are coveted by a lower resistive material 235. The center of the tubes may be filled with a dielectric or it may remain as an air gap.

FIG. 2A is a diagram of a side cross section view of a via 201 similar to that of FIG. 1. The via is formed through a silicon substrate 203 which has front side 209 and back side 215 dielectric cap layers. Active circuitry 207 is formed over the silicon substrate 203 and insulated by a front side dielectric 211. Metallization layers 213, 217 are formed on either side of the silicon substrate and these metallization layers are connected together by the via 201. In this example, a cylindrical dielectric layer 231 has been formed in the middle of the via and this is surrounded with a metal fill 233 with a circular cross section that encircles the dielectric. The lower resistance skin layer 235 is on the outside of the cylindrical metal layer and also on the inside 237 of the cylindrical layer. A dielectric 225 surrounds all of the conductive layers.

FIG. 2B is a diagram of a cross-sectional top view of the same via 201 taken along line 213 in FIG. 2A. Here it can be seen that the via can be formed by first creating the dielectric layer 225 then applying the outer skin layer 235 to the via. A conformal metal deposition 233 can then be deposited into the remaining via forming a cylindrical hole in the center of the via 201. This hole may be lined with a second inner highly conductive skin layer 237. The remaining open area of the via may be filled with dielectric 231 or left as an air gap. The cylindrical tubes of higher conductive material formed on the inside and outside of the tube of ordinary metal provide two skin layers on the normal metal fill. The skin effect is then taken advantage of for higher conductivity both on the inside and the outside of the ordinary metal layer 233. These concentric rings of material allow quick conductivity and high frequency signal transfer through the entire via.

As shown in FIG. 2B and sonic of the subsequent drawings, a cylindrical or tube type metal fill is used. Both sides, the outer and the inner surface of the cylinder or tube of metal fill, are covered by a lower resistive, or higher conductive material, such as Ag, graphene, etc. The center of the cylinder or tube may be filled with a dielectric material, or remain as an air gap.

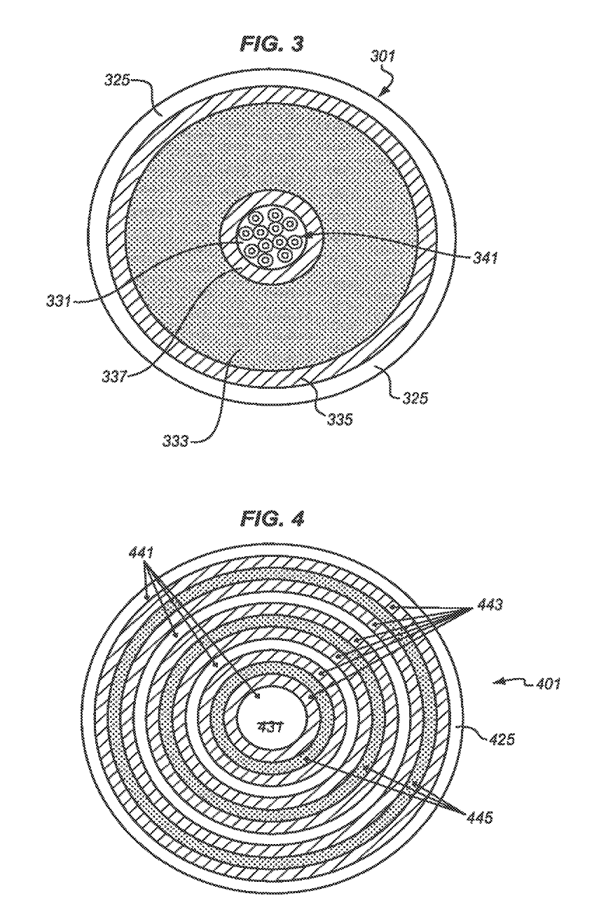

FIG. 3 is a diagram of a cross sectional top view of an alternative embodiment of the via of FIG. 2B. In the example of FIG. 2B the central core 231 is filled with dielectric or left as an air gap. This central dielectric area is surrounded by concentric rings 237, 233, 235 of conductive material. In the example of FIG. 3, a via 301 has been filled with a dielectric layer 325 and outer conductive skin layer 335. A metal fill layer 333 and an inner higher conductive skin layer 337. FIG. 3 shows a cylinder or tube type of conductor fill with inner and outer surfaces that are both covered by a lower resistive material

As in the example of FIG. 2B, the inner core of these concentric rings of conductive material is not filled with conductive metal (e.g. copper). This inner cylindrical area 331 is instead filled with a set of carbon nanotubes 341. Carbon nanotubes are highly conductive and low cost structures however they are costly to form. The large central area and cylindrical high walls of the conductive via's core 331 provides a favorable environment for growing the carbon nanotubes 341. The high conductivity of the carbon nanotubes may be used to significantly improve the conductivity of the via at higher frequencies.

FIG. 4 is a diagram of a top cross sectional view of a via 401 similar to that of FIGS. 2B and 3. In the example of FIG. 4, a cylindrical or tube type conductor fill metal has an inner and an outer surface covered by a lower resistive material. The center is filled with dielectric (isolating) material or an air gap. Multiple concentric rings of higher and lower conductive materials are formed within the via to provide more area, i.e. more skin layers for the skin effect to conduct current through the via. In the example of FIG. 4, the via is first coated with a dielectric isolation layer 425, then successive layers of a higher conductive metal 443 are followed by a layer of lower conductive metal 445. Each tube of fill metal 445 is surrounded on its inner and outer surfaces by a skin layer. The skin layers for successive fill metal tubes are separated by a layer or tube of dielectric 441. The conductive cylindrical tubes 445 surrounded on inner and outer surfaces by highly conductive skin layers 443 create a set of shielded transmission lines that are concentric about the central core 431. The central core 431 may contain air, a dielectric, or, as in the example of FIG. 3, a bundle of carbon nanotubes, or some other filling.

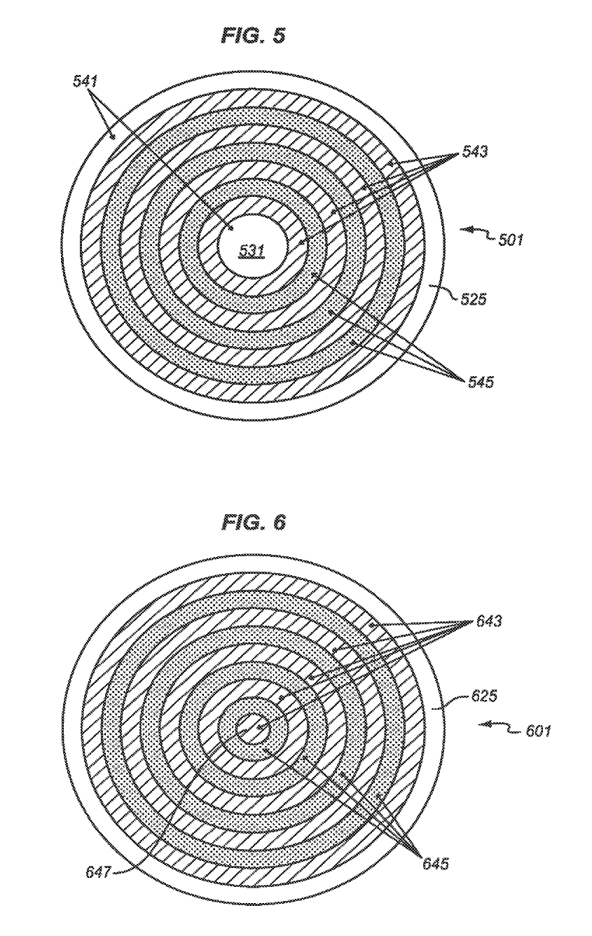

FIG. 5 shows an alternate cross-sectional top view of a via 501 that is lined with a dielectric isolation layer 541. While the example of FIG. 4 uses a set of independent metal tubes with skin layers on the inside and outside and a dielectric gap in between, in the example of FIG. 5 higher conductive and lower conductive layers simply alternate from the outer perimeter of the via toward its inner core 531. As shown, the first conductive layer is a highly conductive layer 543. This surrounds a lower conductive metal cylindrical tube 545. This surrounds another lower conductive layer 543 which surrounds another higher conductive layer 545. As a result, there are three conductive cylindrical tubes surrounded on either side by four higher conductive low resistant skin layers 543. As in the previous examples, the center 531 may be filled with a dielectric or some other material.

In the example of FIG. 6, a top cross-sectional diagram of a cylindrical via 601, the via has alternating layers of high and low conductivity materials 643, 645 isolated by a dielectric outer layer 625. However, at the center of the via there is one more conductive cylindrical tube 645 with a central core 647 of higher conductive skin layer. A multi-layer tube with low resistive surface layers fills the via separated from Si substrate by dielectric isolating layers. The examples of FIGS. 2B, 3, 4, 5, and 6 provide various alternatives or embodiments to applying skin layers to the metal fill. Skin layers may be shared between adjacent copper layers and skin layers may progress from the very middle to an outer ring. The central core may be filled with a carbon nanotube bundle, by a dielectric, or by yet another metal fill. Other variations similar to those shown or described may also be used depending on the particular implementation. Each variation provides different costs and benefits and may be preferred depending on the size of the via, the frequencies of transmission, and other factors.

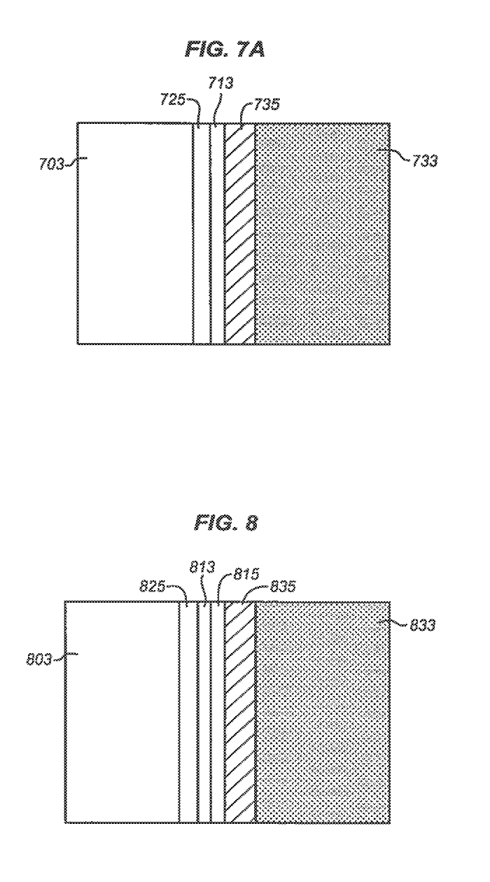

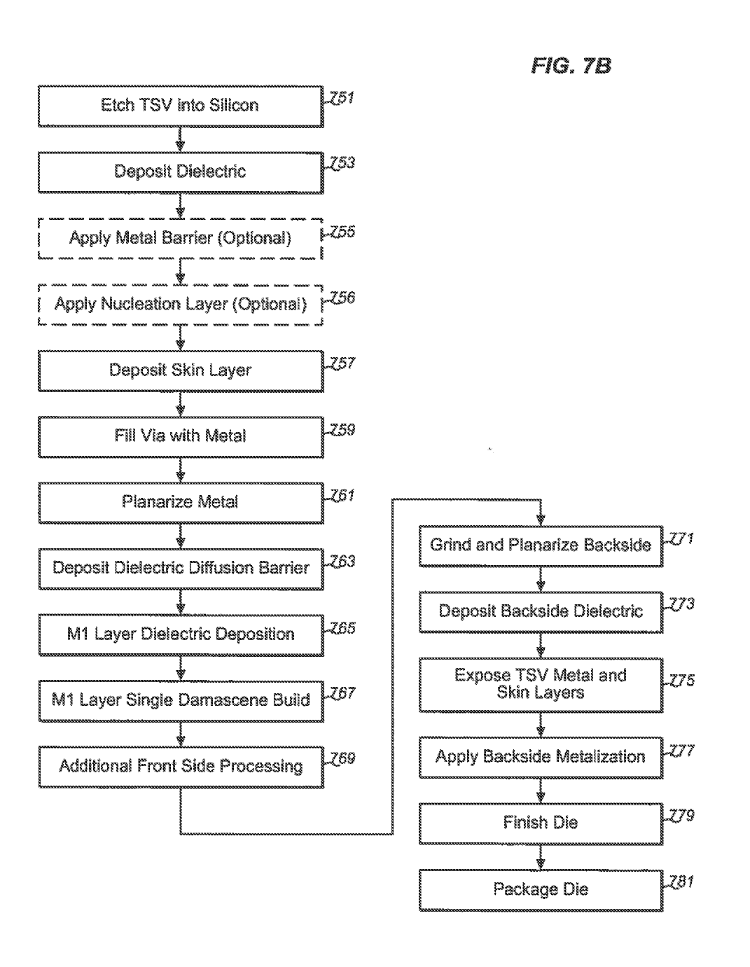

FIG. 7A is a side cross-sectional diagram of a portion of a via showing how layers may be built up in a manufacturing process. The outer layer 703 is a silicon substrate which is formed in any of a variety of conventional ways. The via is formed first by etching the through silicon via (TSV) into the silicon substrate. This is indicated as block 751 in the flow chart of FIG. 7B. After the via has been etched, a dielectric isolation layer 725 is deposited at 753. The dielectric may be a silicon dioxide or any of a variety of other possible dielectrics. It may be deposited using CVD (Chemical Vapor Deposition) or any other suitable technique. As shown in the cross-sectional diagram for example of FIG. 2B, the dielectric is deposited on the inner walls of the etched silicon via. At 755 an optional metal barrier is applied to the dielectric layer. The metal barrier is shown as layer 713 in FIG. 7A the metal barrier may be any of a variety of different metals for example Ti, TiN, Ta, TaN, Ru, WN, etc. deposited by PVD (Physical Vapor Deposition) CVD (Chemical Vapor Deposition), ALD (Atomic Layer Deposition) etc. The metal barrier serves to block the migration of ions from the metals into the silicon substrate it also serves as a seed layer for the conductive metal layers that are deposited on it.

At 757 the skin layer is deposited. As mentioned above, the skin layer 735 is a higher conductivity, lower resistance layer applied as a thin layer against the metal barrier. The skin layer may be applied for example by silver electro plating, electro less plating, PVD, ALD, or in any of a variety of other ways. At 759 a fill metal 733 is filled into the via. This may be performed by metal (e.g. copper) electro-plating, CVD, or in any of a variety of ways. As mentioned above, the fill metal has a lower conductivity than the skin layer metal.

At 761 the metal and bather layers are planarized using, for example, a chemical mechanical planarization (CMP) process. This process may be extended through the fill metal, skin layer, and barrier layer, and then stop at the dielectric isolation layer. At 763 a dielectric diffusion barrier may be deposited on the dielectric to prevent metal ion diffusion provided by the metal fill of the TSV. Different diffusion barriers may be deposited including SiC, SiCN, Si₃N₄ and others.

At 765 a further M1 dielectric deposition operation may be performed, for example with silicon dioxide, a low or ultra-low K dielectric deposition etc. At 767 an M1 layer single damascene build may be performed. This may involve applying a barrier seed and metal (e.g. copper) fill for contacting the skin layer and the TSV metal fill. At 769 any additional front side processing is performed. Subsequent multiple level interconnect stack manufacturing may be done to apply additional levels up to the final passivation and pad opening levels on the front side of the wafer.

At 771 the back side of the wafer is processed first by a back side grinding or a chemical mechanical planarization to expose the fill and the skin layers in the TSV. At 773 the backside dielectrics are deposited such as silicon dioxide. At 775 the TSV's fill metal and skin layers are exposed and at 777 the backside metallization layers are applied to connect the TSV fill metal with contact pads, metal lines or other structures through which connections can be made to external components. At 779 the die is finished with any other additional layers or other materials and at 781 the die is packaged by attachment to a substrate, by encapsulating, by covering, or by any other desired way. The resulting finished die has highly conductive high frequency through silicon vias.

FIG. 8 shows an alternative to the fabrication of FIG. 7A in which a nucleation layer 815 is used between a skin layer 835 and a metal barrier layer 813. As in the example of FIG. 7A, a via has been formed through the silicon substrate. The outer walls of the via have been lined with, a dielectric isolation 825 layer. An optional barrier 813 has been applied to the dielectric 825. This metal barrier layer is not required, however, to accomplish the high frequency conductivity described herein. A nucleation layer such as nickel or copper 815 is then applied to the metal barrier layer. This layer may be used for catalytic nucleation and improves graphene deposition. The catalytic nucleation process is indicated at 756 of FIG. 7B. After the nucleation layer is applied, a low resistive skin layer 835 is applied at 757. In the case of a graphene skin layer, the nucleation layer acts as a seed layer to support or enable the growth of the graphene on the nucleation layer. Other skin layers may also be applied over the nucleation layer, depending on the particular implementation. After the skin layer 835 has been applied at 757, the via may be filled with metal 833 as described above. The die may be finished using all of the operations shown and described in FIG. 7B. The process of FIG. 7B may be modified to include the creation of additional skin layers and metal fill layers as shown in the examples of FIGS. 3, 4, 5, and 6 depending on the particular implementation.

The graphene material may be applied in any of a variety of different ways. Graphene layers or graphene nano ribbons (GNR) may be deposited by CVD or by Plasma-Enhanced CVD processes on catalytic nucleation layers. The nucleation layers may be Ni, Cu, Pd, Ru, or in any of variety of other materials, The CVD may be done in a hydro-carbon atmosphere, such as CH₄, C₂H₄, H₂, etc.) at temperatures above about 800° C. If this type of process is used, the TSV fill with graphene skin layers should be performed in the early phase of the chip manufacturing, This prevents, the higher temperatures (above 800° C.) from negatively influencing the die or the properties of the die's transistors. After deposition, the resistivity of the graphene multi-layers or GNRs may be reduced or the conductivity may be increased by intercalation doping with AsF₅, FeCl₃, SbF₅, etc. For other graphene application processes other precautions may be taken as appropriated depending on the particular implementation.

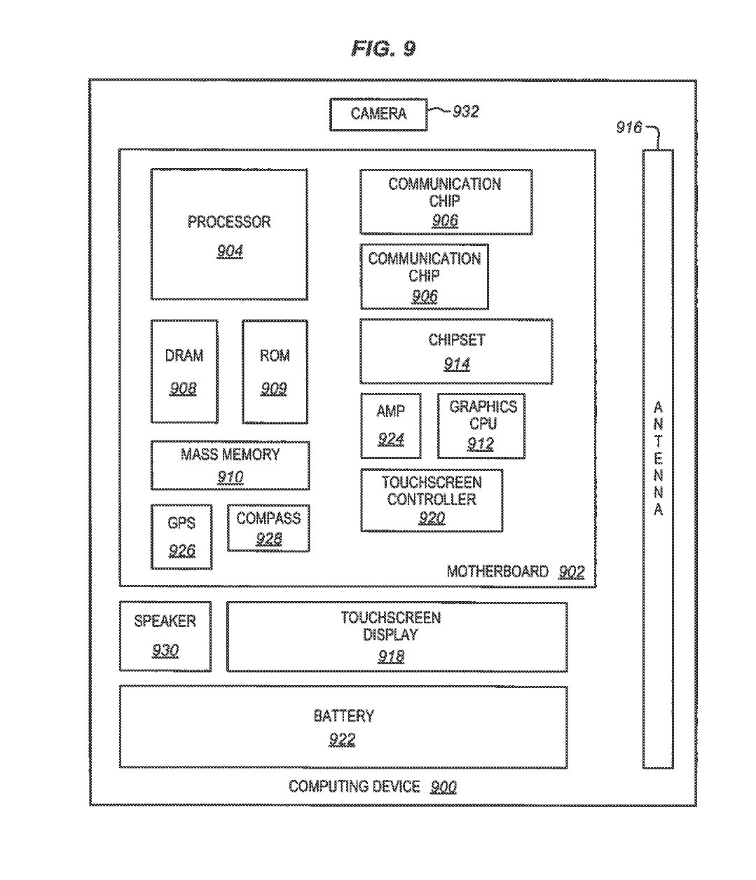

FIG. 9 illustrates a computing device 900 in accordance with one implementation of the invention. The computing device 900 houses a system board 902. The board 902 may include a number of components, including but not limited to a processor 904 and at least one communication package 906. The communication package is coupled to one or more antennas 916. The processor 904 is physically and electrically coupled to the board 902. At least one antenna 916 integrated with a communication package 906 and is physically and electrically coupled to the hoard 902 through the package. In some implementations of the invention, any one or more of the components, controllers, hubs, or interfaces are formed on dies using through silicon vias as described above.

Depending on its applications, computing device 900 may include other components that may or may not be physically and electrically coupled to the hoard 902. These other components include, but are not limited to, volatile memory (e.g., DRAM) 908, non-volatile memory (e.g., ROM) 909, flash memory (not shown), a graphics processor 912, a digital signal processor (not shown), a crypto processor (not shown), a chipset 914, an antenna 916, a display 918 such as a touchscreen display, a touchscreen controller 920, a battery 922, an audio codec (not shown), a video codec (not shown), a power amplifier 924, a global positioning system (GPS) device 926, a compass 928, an accelerometer (not shown), a gyroscope (not shown), a speaker 930, a camera 932, and a mass storage device (such as hard disk drive) 910, compact disk (CD) (not shown), digital versatile disk (DVD) (not shown), and so forth). These components may be connected to the system board 902, mounted to the system board, or combined with any of the other components.

The communication package 906 enables wireless and/or wired communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication package 906 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, its CDMA, TDMA, DECT, Bluetooth, Ethernet derivatives thereof, as well as any other wireless and wired protocols that are designated as 3G, 4G, 5G, and beyond. The computing device 900 may include a plurality of communication packages 906. For instance, a first communication package 906 may be dedicated to shorter range wireless communications such as Wi-Fi and Bluetooth and a second communication package 906 may be dedicated to longer range wireless communications such as GPS, EDGE, GPRS, CDMA, WiMAX, LTE, Ev-DO, and others.

The processor 904 of the computing device 900 includes en integrated circuit die packaged within the processor 904. The term “processor” may refer to any device or portion of a device that processes electronic data from registers and/or memory to transform that electronic data into other electronic data that may be stored in registers and/or memory.

In various implementations, the computing device 900 may be a laptop, a netbook, a notebook, an ultrabook, a smartphone, a tablet, a personal digital assistant (PDA), an ultra mobile PC, a mobile phone, a desktop computer, a server, a printer, a scanner a monitor, a set-top box, an entertainment control unit, a digital camera, a portable music player, or a digital video recorder. In further implementations, the computing device 900 may be any other electronic device that processes data.

Embodiments may be implemented as a part of one or more memory chips, controllers, CPUs (Central Processing Unit), microchips or integrated circuits interconnected using a motherboard, an application specific integrated circuit (ASIC), and/or a field programmable gate array (FPGA).

References to “one embodiment”, “an embodiment”, “example embodiment”, “various embodiments”, etc., indicate that the embodiment(s) of the invention so described may include particular features, structures, or characteristics, but not every embodiment necessarily includes the particular features, structures, or characteristics, Further, some embodiments may have some, all, or none of the features described for other embodiments.

In the following description and claims, the term “coupled” along with its derivatives, may be used. “Coupled” is used to indicate that two or more elements co-operate or interact with each other, but they may or may not have intervening physical or electrical components between them.

As used in the claims, unless otherwise specified, the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

The drawings and the forgoing description give examples of embodiments. Those skilled in the art will appreciate that one or more of the described elements may well be combined into a single functional element. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of embodiments is by no means limited by these specific examples. Numerous variations, whether explicitly given in the specification or not, such as differences in structure, dimension, and use of material, are possible. The scope of embodiments is at least as broad as given by the following claims.

The following examples pertain to further embodiments. The various features of the different embodiments may be variously combined with some features included and others excluded to suit a variety of different applications. Some embodiments pertain to a through silicon via in a silicon die to connect a first metal layer to a second metal layer. The through silicon via has a channel through at least a portion of the silicon die, a first conductive layer extending through the via, the first conductive layer having an outer surface and a first electrical conductivity, and a second conductive layer covering the outer surface of the first conductive layer, the second conductive layer having a second electrical conductivity higher than the first electrical conductivity.

Further embodiments include a metal bather layer surrounding the first and second layer within the via. Further embodiments include a dielectric layer surrounding the second conductive layer to isolate the first and second conductive layer from the silicon substrate. In further embodiments, the first conductive layer has an inner surface, the via further comprising a third conductive layer covering the inner surface, the third conductive layer having the second electrical conductivity. Further embodiments include a dielectric region, wherein the inner surface of the first conductive layer surrounds the dielectric region.

In further embodiments, the via is cylindrical and the first conductive layer is cylindrical and wherein the center of the via is filled with dielectric. In further embodiments, the via is cylindrical and the first conductive layer is cylindrical and wherein the center of the via is filled with carbon nanotubes. In further embodiments, the via is cylindrical and the first conductive layer is cylindrical and wherein the center of the via is filled with a plurality of cylindrical tubes having the first electrical conductivity.

In further embodiments, the plurality of cylindrical tubes each have a higher conductivity skin layer on an outer surface. In further embodiments, the plurality of cylindrical tubes each have a higher conductivity skin layer on an inner surface. In further embodiments, the tubes of the plurality of cylindrical tubes are concentric and are isolated from each other each by one of a plurality of concentric dielectric layers. In further embodiments, the first conductive layer is copper and the second conductive layer is silver. In further embodiments, the first conductive layer is copper and the second conductive layer is graphene.

Some embodiments pertain to a method that includes creating a via through a silicon substrate, depositing a dielectric on a surface of the via, depositing a second conductive layer having a second electrical conductivity on the dielectric surface, depositing a first conductive layer having a first lower electrical conductivity within the via surrounded by and adjacent to the second conductive layer, and applying metallization to the via to form electrical connections to the via.

In further embodiments depositing a second conductive layer comprises filling the via. Further embodiments include creating a cylindrical opening in the center of the via and filling the opening with a dielectric. Further embodiments include creating a cylindrical opening in the center of the via and filling the via with carbon, nanotubes. Further embodiments include creating a cylindrical opening in the center of the via and filling the via with graphene cylinders. Further embodiments include creating a cylindrical opening in the center of the via and filling the via with a plurality of copper cylinders. In further embodiments, the copper cylinders are concentric.

In further embodiments wherein depositing a first conductive layer comprises depositing a plurality of concentric cylindrical layers with a concentric cylindrical layer having the second electrical conductivity between each concentric cylindrical layer of the first conductive layer.

Further embodiments include depositing a metal barrier layer on the dielectric surface and wherein depositing a second conductive layer comprises depositing the second conductive layer on the metal barrier layer.

In further embodiments the second conductive layer is graphene and depositing a second conductive layer comprises applying a nucleation layer and depositing graphene over the nucleation layer. Further embodiments include packaging the silicon substrate after applying metallization to form a packaged semiconductor die.

Some embodiments pertain to a computer system with a user interface to receive input from a user, a display to display results to the user, and a processor in a package to receive the user inputs and generates results to provide to the display, the processor package having a plurality of through vim, at least one of the through silicon vias having a channel through a silicon substrate, a first conductive layer extending through the via, the lust conductive layer having an outer surface and a first electrical conductivity, and a second conductive layer covering the outer surface of the first conductive layer, the second conductive layer having a second electrical conductivity higher than the first electrical conductivity.

In further embodiments, the via further comprises a plurality of additional conductive layers of the first electrical conductivity formed concentrically within the via and each separated by an additional conductive layer of the second electrical conductivity. In further embodiments the plurality of additional conductive layers are further separated each by an additional dielectric layer.

1-28. (canceled)

29. In a silicon die, a through silicon via to connect. a first metal layer to a second metal layer, the through silicon via comprising:
a channel through at least a portion of the silicon die;
a first conductive layer extending through the via, the first conductive layer having an outer surface and a first electrical conductivity; and
a second conductive layer covering the outer surface of the first conductive layer, the second conductive layer having a second electrical conductivity higher than the first electrical conductivity.

30. The via of claim 29, further comprising a metal barrier layer surrounding the first and second layer within the via.

31. The via of claim 29, further comprising a dielectric layer surrounding the second conductive layer to isolate the first and second conductive via from the silicon substrate.

32. The via of claim 29, wherein the first conductive layer has an inner surface, the via further comprising a third conductive layer covering the inner surface, the third conductive layer having the second electrical conductivity.

33. The via of claim 32, further comprising a dielectric region, wherein the inner surface of the first conductive layer surrounds the dielectric region.

34. The via of claim 33, wherein the via is cylindrical and the first conductive layer is cylindrical and wherein the center of the via is filled with dielectric.

33. The via of claim 33, wherein the via is cylindrical and the first conductive layer is cylindrical and wherein the center of the via is filled with carbon nanotubes.

36. The via of claim 33, wherein the via is cylindrical and the first conductive layer is cylindrical and wherein the center of the via is filled with a plurality of cylindrical tubes having the first electrical conductivity.

36. The via of claim 36, wherein the tubes of the plurality of cylindrical tubes each have a higher conductivity skin layer on an outer surface.

38. The via of claim 36, wherein the tubes of the plurality of cylindrical tubes each have a higher conductivity skin layer on an inner surface.

39. The via of claim 36, wherein the tubes of the plurality of cylindrical tubes are concentric and are isolated from each other each by one of a plurality of concentric dielectric layers.

40. The via of claim 29, wherein the first conductive layer is copper and the second conductive layer is silver.

29. The via of claim 29, wherein the first conductive layer is copper and the second conductive layer is graphene.

42. A method comprising:
creating a via through a silicon substrate;
depositing a dielectric on a surface of the via;
depositing a second conductive layer having a second electrical conductivity on the dielectric surface;
depositing a first conductive layer having a first lower electrical conductivity within the via surrounded by and adjacent to the second conductive layer; and
applying metallization to the via to form electrical connections to the via.

43. The method of claim 42, wherein depositing a second conductive layer comprises filling the via.

43. The method of claim 43, further comprising creating a cylindrical opening in the center of the via and filling the opening with a dielectric.

45. The method of claim 42, wherein depositing a first conductive layer comprises depositing a plurality of concentric cylindrical layers with a concentric cylindrical layer having the second electrical conductivity between each concentric cylindrical layer of the first conductive layer.

46. A computer system comprising:
a user interface to receive input from a user;
a display to display results to the user;
a processor in a package to receive the user inputs and generates results to provide to the display, the processor package having a plurality of through silicon vias, at least one of the through silicon vias having a channel through a silicon substrate, a first conductive layer extending through the via, the first conductive layer having an outer surface and a first electrical conductivity, and a second conductive layer covering the outer surface of the first conductive layer, the second conductive layer having a second electrical conductivity higher than the first. electrical conductivity.

46. The system of claim 46, wherein the via further comprises a plurality of additional conductive layers of the first electrical conductivity formed concentrically within the via and each separated by an additional conductive layer of the second electrical conductivity.

47. The system of claim 47, wherein the plurality of additional conductive layers are further separated each by an additional dielectric layer.
